(19) United States
(12) Patent Application Publication
(10) Pub. No.: US 2017/0207269 A1
(43) Pub. Date: Jul. 20, 2017

(54) IMAGE SENSOR CONTACT ENHANCEMENT

(71) Applicant: OMNIVISION TECHNOLOGIES, INC., Santa Clara, CA (US)

(72) Inventor: Lequn Liu, Sunnyvale, CA (US)

(21) Appl. No.: 14/995,833

(22) Filed: Jan. 14, 2016

(51) Int. Cl. H01L 27/146

(52) U.S. Cl. CPC H01L 27/14636; H01L 27/14643; H01L 27/1463; H01L 27/14689

(57) ABSTRACT

An image sensor includes a photodiode disposed in semiconductor material. The photodiode is one of a plurality of photodiodes formed in an array. The image sensor also includes a floating diffusion disposed in the semiconductor material, and the floating diffusion is disposed adjacent to the photodiode in the plurality of photodiodes. A transfer gate is disposed to transfer image charge generated in the individual photodiode into the floating diffusion. Peripheral circuitry is disposed in the semiconductor material and includes a first electrical contact to the semiconductor material. A first silicide layer is disposed on the floating diffusion, a second silicide layer is disposed on the transfer gate, and a third silicide layer is disposed on the first electrical contact to the semiconductor material.

### TECHNICAL FIELD

This disclosure relates generally to image sensors, and in particular but not exclusively, relates to electrical contact enhancement.

### BACKGROUND INFORMATION

Image sensors have become ubiquitous. They are widely used in digital still cameras, cellular phones, security cameras, as well as, medical, automobile, and other applications. The technology used to manufacture image sensors has continued to advance at a great pace. For example, the demands of higher resolution and lower power consumption have encouraged the further miniaturization and integration of these devices.

Semiconductor device performance (including image sensor device performance) is directly related to the types of metal-semiconductor junctions employed within the device. Depending on the work function of the metal and the location of conduction/valence band edge of the semiconductor, junctions with a wide array of electrical characteristics may be created. If there is a substantial mismatch between the work function of the metal and the location of the conduction/valence band edge of the semiconductor, a Schottky barrier may be formed. Although construction of a Schottky barrier is desirable in some applications (e.g., in Schottky diodes, Schottky transistors, and metal-semiconductor field effect transistors) where unimpeded charge transfer between the semiconductor and the metal is desired, a Schottky barrier may inhibit device performance.

### BRIEF DESCRIPTION OF THE DRAWINGS

Non-limiting and non-exhaustive examples of the invention are described with reference to the following figures, wherein like reference numerals refer to like parts throughout the various views unless otherwise specified.

FIG. 1A is an illustration of a top down view of an example image sensor, in accordance with the teachings of the present invention.

FIG. 1B is a cross sectional illustration of the example image sensor of FIG. 1A, in accordance with the teachings of the present invention.

FIG. 2 is a block diagram illustrating one example of an imaging system including the image sensor of FIGS. 1A and 1B, in accordance with the teachings of the present invention.

FIGS. 3A-3D show an example process for forming the image sensor of FIGS. 1A and 1B, in accordance with the teachings of the present invention.

Corresponding reference characters indicate corresponding components throughout the several views of the drawings. Skilled artisans will appreciate that elements in the figures are illustrated for simplicity and clarity and have not necessarily been drawn to scale. For example, the dimensions of some of the elements in the figures may be exaggerated relative to other elements to help to improve understanding of various embodiments of the present invention. Also, common but well-understood elements that are useful or necessary in a commercially feasible embodiment are often not depicted in order to facilitate a less obstructed view of these various embodiments of the present invention.

### DETAILED DESCRIPTION

Examples of an apparatus and method for image sensor contact enhancement are described herein. In the following description, numerous specific details are set forth to provide a thorough understanding of the examples. One skilled in the relevant art will recognize, however, that the techniques described herein can be practiced without one or more of the specific details, or with other methods, components, materials, etc. In other instances, well-known structures, materials, or operations are not shown or described in detail to avoid obscuring certain aspects.

Reference throughout this specification to “one example” or “one embodiment” means that a particular feature, structure, or characteristic described in connection with the example is included in at least one example of the present invention. Thus, the appearances of the phrases “in one example” or “in one embodiment” in various places throughout this specification are not necessarily all referring to the same example. Furthermore, the particular features, structures, or characteristics may be combined in any suitable manner in one or more examples.

Throughout this specification, several terms of art are used. These terms are to take on their ordinary meaning in the art from which they come, unless specifically defined herein or the context of their use would clearly suggest otherwise. It should be noted that element names and symbols may be used interchangeably through this document (e.g., Si vs. silicon); however, both have identical meaning.

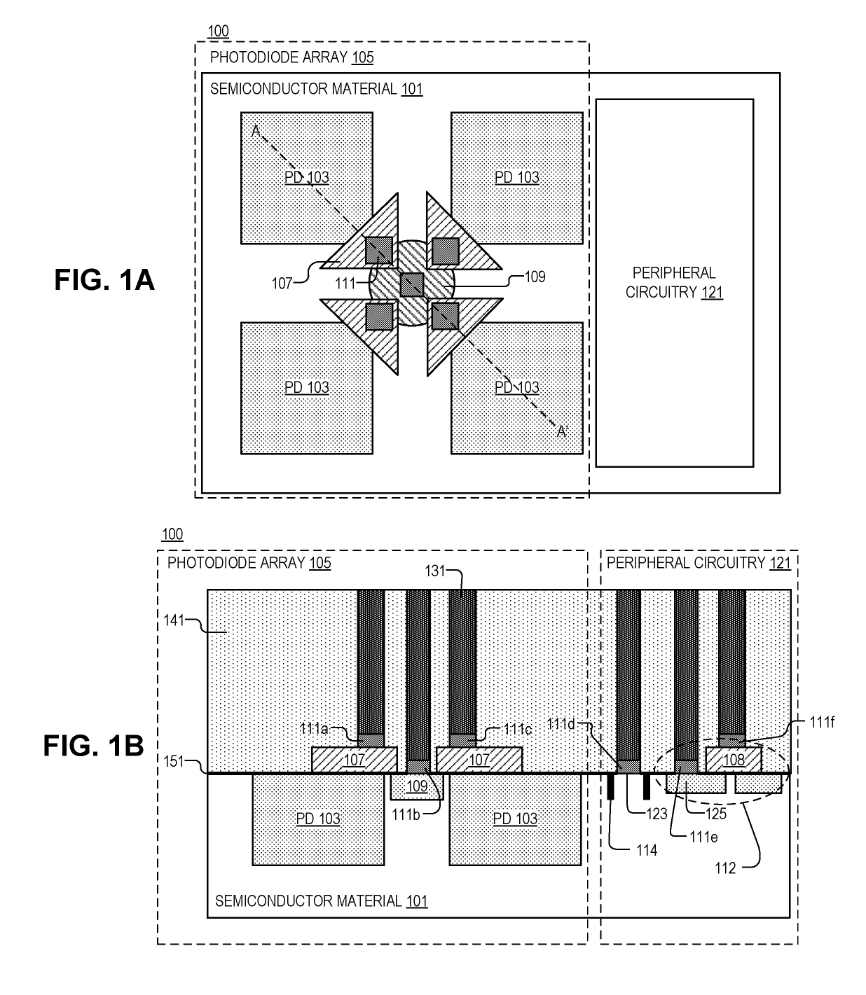

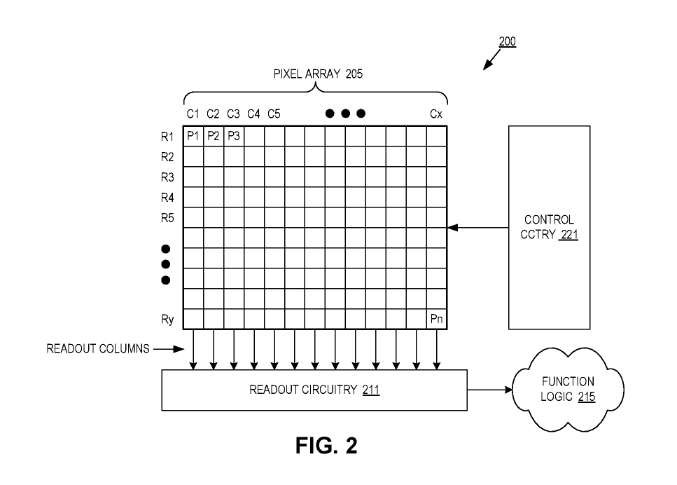

FIG. 1A is an illustration of a top down view of an example image sensor 100. It is worth noting that the depicted top down view of image sensor 100 is omitting isolation layer 141, plurality of metal interconnects 131, and gate oxide 151 in order to avoid obscuring the underlying device architecture (see infra FIG. 1B). In the depicted example, image sensor 100 includes: semiconductor material 101, plurality of photodiodes 103 (arranged into photodiode array 105), transfer gate 107, floating diffusion 109, silicide layers 111, and peripheral circuitry 121. As shown, plurality of photodiodes 103 is arranged into an array 105 including four photodiodes 103. Four transfer gates 107 are disposed in the center of plurality of photodiodes 103 and are positioned to transfer image charge from plurality of photodiodes 103 into floating diffusion 109. Floating diffusion 109 is located in the center of the four photodiodes 103 and is circular. In one example, transfer gate 107 includes polysilicon and may be doped. Although the depicted example shows four photodiodes 103, in one or more examples, plurality of photodiodes 103 can include any number of photodiodes 103 coupled to floating diffusion 109 including two, six, and eight photodiodes. Additionally, the orientation of the photodiode array 105 may not be square and may take any other configuration such as circular, or the like. Furthermore, although in the depicted example peripheral circuitry 121 is disposed on the right edge of semiconductor material 101, peripheral circuitry 121 may be disposed in any location around the photodiode array 105 and may surround photodiode array 105.

FIG. 1B is a cross sectional illustration of the example image sensor 100 of FIG. 1A as cut along line A-A′. In the depicted example, semiconductor material 101 includes a plurality of photodiodes 103 disposed in semiconductor material 101, and plurality of photodiodes 103 form an array 105. In many examples, plurality of photodiodes 103 may include a p+ pinning layer disposed at the interface of gate oxide 151 and semiconductor material 101. Floating diffusion 109 is disposed in semiconductor material 101, and floating diffusion 109 is disposed adjacent to an individual photodiode 103 in plurality of photodiodes 103. Transfer gate 107 is disposed to transfer image charge generated in the individual photodiode 103 into floating diffusion 109. Gate oxide 151 is disposed between transfer gate 107 and semiconductor material 101. It should be noted that the thickness of gate oxide 151 in peripheral circuitry 121 may be different than the thickness of gate oxide 151 in photodiode array 105. Further, in one or more examples, a selective etch layer may be disposed on gate oxide 151 (between gate oxide 151 and isolation layer 141) to facilitate selective etching of gate oxide 151 and underling semiconductor material 101. In the depicted example, a first lateral edge of transfer gate 107 is disposed above the individual photodiode 103, and a second lateral edge of transfer gate 107 is disposed above floating diffusion 109. Peripheral circuitry 121 is also disposed in semiconductor material 101 and includes first electrical contact 123 to semiconductor material 101. Peripheral circuitry 121 also includes transistor 112 with source terminal 125 and transfer gate 108. In one example, first electrical contact 123 to semiconductor material 101 is isolated by shallow trench isolation 114, which may include an oxide or heavily doped semiconductor material.

In the depicted example, first silicide layer 111b is disposed on floating diffusion 109, second silicide layer 111c is disposed on transfer gate 107, and third silicide layer 111d is disposed on first electrical contact 123 to semiconductor material 101 to reduce a contact resistance. It is worth noting that silicide layer 111a is also a second silicide layer (like second silicide layer 111c) and is disposed on another transfer gate 107. First silicide layer 111b, second silicide layer 111c, and third silicide layer 111d may include the same material composition. In one example, all three silicide layers include CoₓSi_{y} or NiₓSi_{y}. However, in another example, the silicide layers may include TiₓSi_{y} or any other appropriate silicon or metal based compound. It should be mentioned that in all aforementioned examples, the silicide chemical structure may take the ideal stoichiometric configuration (e.g., CoSi₂) or any other stoichiometric configuration (e.g., CoSi_{1.5}) that may result from processing steps used to manufacture the silicide layers. Additionally, first silicide layer 111b, second silicide layer 111c, and third silicide layer 111d may include an implant element of carbon, nitrogen, or oxygen to help prevent metal diffusion into the underlying electrode structure.

As shown, isolation layer 141 (or multiple isolation layers) may be disposed proximate to semiconductor material 101, and transfer gate 107 is disposed between semiconductor material 101 and the isolation layer 141. In the depicted example, a plurality of metal interconnects 131 are disposed in the isolation layer 141 and the plurality of metal interconnects are electrically coupled to first silicide layer 111b, second silicide layer 111c, and third silicide layer 111d. In one example, the plurality of metal interconnects 131 include aluminum, tungsten, copper, or any other suitable material. The material composition of metal interconnects 131 may be tuned to lower contact resistance between the silicide layers and metal interconnects 131.

In the example depicted in FIG. 1B, peripheral circuitry 121 may include a transistor 112, fourth silicide layer 111e, and fifth silicide layer 111f. As shown, fourth silicide layer 111e may be disposed on source terminal 125 of transistor 112 and fifth silicide layer 111f may be disposed on gate 108 of transistor 112 to reduce a contact resistance. It should be noted that peripheral circuitry 121 may include other pieces of circuitry and may have other silicide layers and interconnects coupled to electrodes associated with the other pieces of circuitry. For instance, in one example, peripheral circuitry 121 may include control circuitry and readout circuitry, where the control circuitry controls the operation of plurality of photodiodes 103, and readout circuitry reads out image data from the plurality of photodiodes 103.

Although not depicted, in one example, a color filter layer may be optically aligned with plurality of photodiodes 103. The color filter layer may include red, green, and blue color filters which may be arranged into a Bayer pattern, EXR pattern, X-trans pattern, or the like. However, in a different or the same example, the color filter layer may include infrared filters, ultraviolet filters, or other light filters that isolate invisible portions of the EM spectrum. In the same or a different example, a microlens layer is formed on the color filter layer. The microlens layer may be fabricated from a photo-active polymer that is patterned on the surface of the color filter layer. Once rectangular blocks of polymer are patterned on the surface of the color filter layer, the blocks may be melted (or reflowed) to form the dome-like structure characteristic of microlenses.

In one or more examples, other pieces of device architecture may be present in/on image sensor 100 such pinning wells between photodiodes, and electrical isolation structures. In one example, the internal components of image sensor 100 may be surrounded by electrical and/or optical isolation structures. This may help to reduce noise in image sensor 100. Electrical isolation may be accomplished by etching isolation trenches in semiconductor material 101 around individual photodiodes which may then be filled with semiconductor material, oxide material, or the like. Optical isolation structures may be formed by constructing a reflective grid on the surface of semiconductor material 101 disposed beneath a color filter layer. The optical isolation structures may be optically aligned with the plurality of photodiodes.

In operation, image sensor 100 acquires image charge when photons reach plurality of photodiodes 103. A transfer signal is then applied to transfer gate 107 to transfer accumulated image charge into floating diffusion 109 to be read out to readout circuitry. Since almost all of these electrical communications require the transfer of charge from a semiconductor to a metal contact or vice versa, it is imperative that good electrical contact is made between the semiconductors and the metals. Examples in accordance with the teachings of the present invention decrease contact resistance and enhance image sensor performance by employing an intermediary silicide layer between semiconductor material 101 and metal interconnects 131.

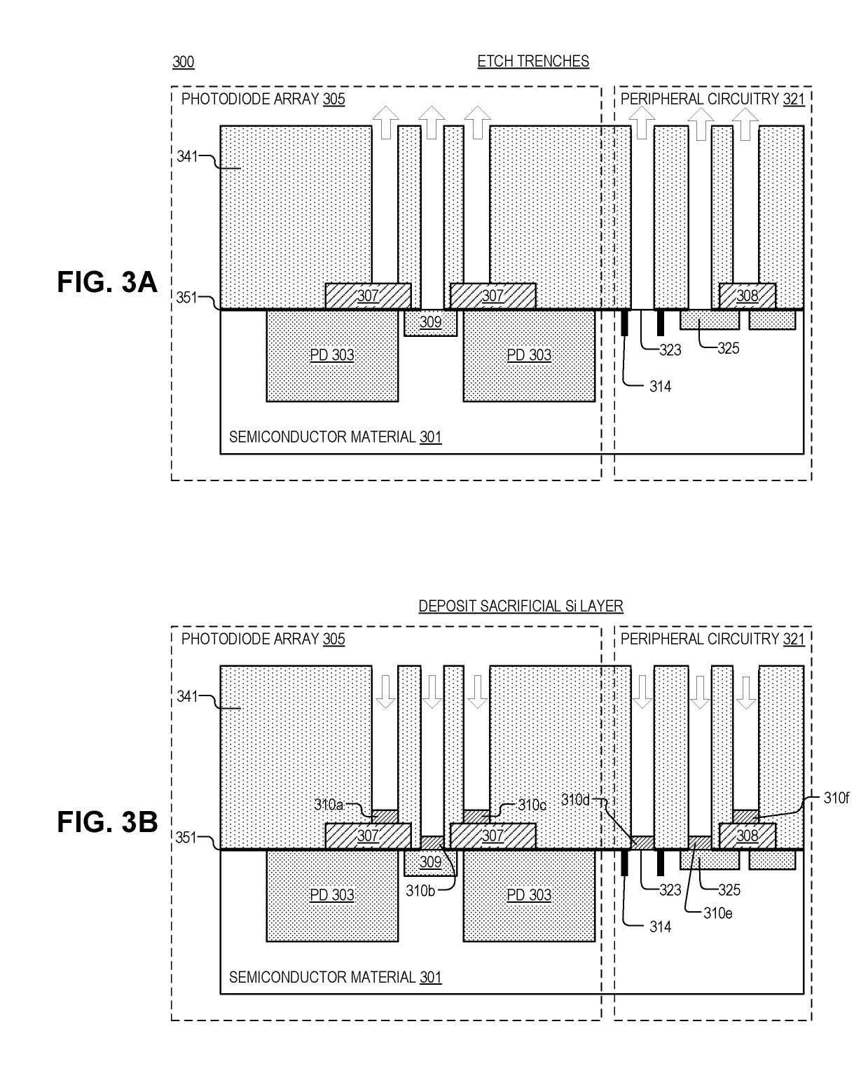

FIG. 2 is a block diagram illustrating one example of an imaging system including the image sensor of FIGS. 1A and 1B. Imaging system 200 includes pixel array 205, control circuitry 221, readout circuitry 211, and function logic 215. In one example, pixel array 205 is a two-dimensional (2D) array of photodiodes, or image sensor pixels (e.g., pixels P1, P2 . . . , Pn). As illustrated, photodiodes are arranged into rows (e.g., rows R1 to Ry) and columns (e.g., column C1 to Cx) to acquire image data of a person, place, object, etc., which can then be used to render a 2D image of the person, place, object, etc. However, the rows and columns do not necessarily have to be linear and may take other shapes depending on use case.

In one example, after each image sensor photodiode/pixel in pixel array 205 has acquired its image data or image charge, the image data is readout by readout circuitry 211 and then transferred to function logic 215. Readout circuitry 211 may be coupled to readout image data from the plurality of photodiodes in pixel array 205, and may be included in the peripheral circuitry (e.g., peripheral circuitry 121). In various examples, readout circuitry 211 may include amplification circuitry, analog-to-digital (ADC) conversion circuitry, or otherwise. Function logic 215 may simply store the image data or even alter/manipulate the image data by applying post image effects (e.g., crop, rotate, remove red eye, adjust brightness, adjust contrast, or otherwise). In one example, readout circuitry 211 may readout a row of image data at a time along readout column lines (illustrated) or may readout the image data using a variety of other techniques (not illustrated), such as a serial readout or a full parallel readout of all pixels simultaneously.

In one example, control circuitry 221 is coupled to pixel array 205 to control operation of the plurality of photodiodes in pixel array 205, and may be included in the peripheral circuitry (e.g., peripheral circuitry 121). For example, control circuitry 221 may generate a shutter signal for controlling image acquisition. In one example, the shutter signal is a global shutter signal for simultaneously enabling all pixels within pixel array 205 to simultaneously capture their respective image data during a single acquisition window. In another example, the shutter signal is a rolling shutter signal such that each row, column, or group of pixels is sequentially enabled during consecutive acquisition windows. In another example, image acquisition is synchronized with lighting effects such as a flash.

In one example, imaging system 200 may be included in a digital camera, cell phone, laptop computer, or the like. Additionally, imaging system 200 may be coupled to other pieces of hardware such as a processor, memory elements, output (USB port, wireless transmitter, HDMI port, etc.), lighting/flash, electrical input (keyboard, touch display, track pad, mouse, microphone, etc.), and/or display. Other pieces of hardware/software may deliver instructions to imaging system 200, extract image data from imaging system 200, or manipulate image data supplied by imaging system 200.

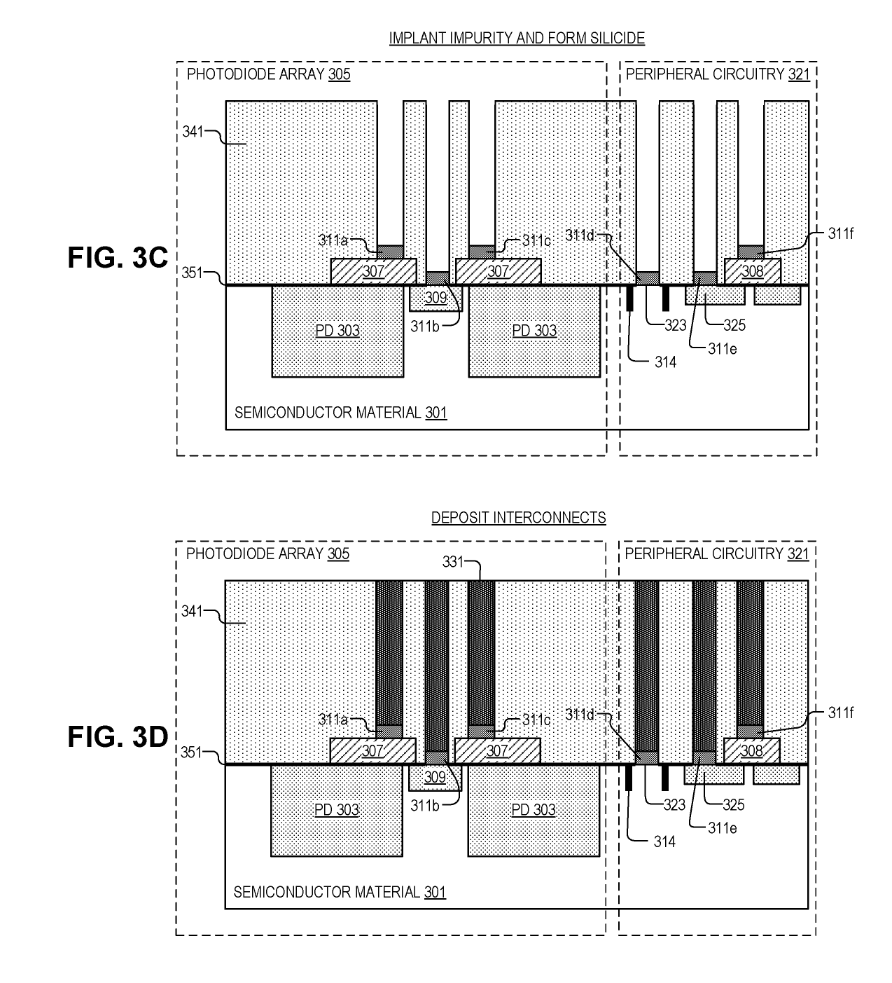

FIGS. 3A-3D show an example process 300 for forming the image sensor of FIGS. 1A and 1B (e.g., image sensor 100). The order in which some or all of FIGS. 3A-3D appear in process 300 should not be deemed limiting. Rather, one of ordinary skill in the art having the benefit of the present disclosure will understand that some of the process 300 may be executed in a variety of orders not illustrated, or even in parallel.

FIG. 3A illustrates providing semiconductor material 301 and etching contact holes in isolation layer 341. In the depicted example, semiconductor material 301 is provided, and includes plurality of photodiodes 303 disposed in semiconductor material 301 and floating diffusion 309 disposed in semiconductor material 301. Peripheral circuitry 321 is also provided and disposed in semiconductor material 301, and includes first electrical contact 323 to semiconductor material 301. Prior to formation of the device depicted in FIG. 3A, transfer gate 307 was formed, and transfer gate 307 is disposed to transfer image charge from an individual photodiode 303 in plurality of photodiodes 303 to floating diffusion 309. Also, isolation layer 341 is formed on a surface of semiconductor material 301. In one example, etching contact holes in isolation layer 341 may include patterning the surface of isolation layer 341 with photoresist (either negative or positive) and using a wet or dry etch to achieve the desired contact holes. In the depicted example, the contact holes extend from the surface of isolation layer 341 to their respective electrodes. Depending on the electrode contacted, contact holes may also be etched in gate oxide 351. It should be noted that although there are only three contact holes depicted in the photodiode array 305 region, and three contact holes depicted in the peripheral circuitry 321 region, many more contact holes connected to other pieces of device architecture may be disposed in both regions, as FIG. 3A depicts a highly simplified cross sectional illustration. Further, it is worth noting that in some examples, a selective etch stop layer may be disposed on gate oxide 351 to help facilitate the etch process.

FIG. 3B is an illustration of selectively depositing silicon layers 310 (e.g., silicon layers 310a-310f) on the contact areas by sending deposition material into the contact holes. In the depicted example, silicon layers 310 are sacrificial, and silicon layers 310 will be implanted with elements (to prevent metal diffusion into the underlying structures). Silicon layers 310 are subsequently completely consumed during the metallization process to form silicide layers 311. Silicon layers 310 may range in thickness from several nanometers to tens of nanometers depending on the thickness of the metal silicide to be formed. Silicon layers 310 may be deposited using atomic layer deposition, molecular beam epitaxy, chemical vapor deposition, or the like.

FIG. 3C is an illustration of implanting impurity elements and consuming silicon layers 310 to form silicide layers 311. Prior to silicidation, impurities such as carbon, nitrogen, oxygen, or the like, are implanted in silicon layers 310, and may prevent metal diffusion into the underlying pieces of device architecture. This may be achieved via a low dose ion implantation process (e.g., 10¹⁴ atoms/cm³). After impurity implantation, silicon layers 310 are consumed completely to form a metal silicide via a metallization process. In one example, the metallization process may include removing a native oxide layer from silicon layers 310, vapor depositing metal on silicon layers 310, thermally cycling to convert silicon layers 310 to a metal-silicon compound (e.g., CoSiₓ), wet cleaning silicon layers 310 to remove unreacted metal, and thermally cycling again to form a metal-silicon compound with the desired stoichiometric configuration (e.g., CoSi₂). The result is that first silicide layer 311b is disposed in the contact holes and on floating diffusion 309, second silicide layer 311c is disposed in the contact holes and on transfer gate 307, and third silicide layer 311d disposed in the contact holes and on first electrical contact 323 (e.g., p+ contact) to the semiconductor material 301. In the depicted example, first silicide layer 311b, second silicide layer 311c, and third silicide layer 311d include the same material composition such as CoₓSi_{y} or NiₓSi_{y}. However, in a different example silicide layers 311 may have different material composition among one another, and may include other metals (such as Co, Ni, Ta, Ti, Zn, In, Pb, Ag, etc.) and semiconductor elements.

FIG. 3D is an illustration of forming metal interconnects 331 in isolation layer 341. Metal interconnects 331 are electrically coupled to first silicide layer 311b, second silicide layer 311c, and third silicide layer 311d and may be deposited via thermal evaporation, or the like. Residual metal may be removed from the surface of the isolation layer 341 via chemical mechanical polishing. Metal interconnects 331 may include aluminum, tungsten, copper, or other suitable conductive materials, and may form Ohmic contacts with first silicide layer 311b, second silicide layer 311c, and third silicide layer 311d.

The above description of illustrated examples of the invention, including what is described in the Abstract, is not intended to be exhaustive or to limit the invention to the precise forms disclosed. While specific examples of the invention are described herein for illustrative purposes, various modifications are possible within the scope of the invention, as those skilled in the relevant art will recognize.

These modifications can be made to the invention in light of the above detailed description. The terms used in the following claims should not be construed to limit the invention to the specific examples disclosed in the specification. Rather, the scope of the invention is to be determined entirely by the following claims, which are to be construed in accordance with established doctrines of claim interpretation.

1. An image sensor, comprising:
a photodiode disposed in semiconductor material, wherein the photodiode is one of a plurality of photodiodes which form an array;
a floating diffusion disposed in the semiconductor material, wherein the floating diffusion is disposed adjacent to the photodiode in the plurality of photodiodes;
a transfer gate disposed to transfer image charge generated in the photodiode into the floating diffusion, wherein a gate oxide is disposed on the semiconductor material between the transfer gate and the semiconductor material;
peripheral circuitry disposed in the semiconductor material including a first electrical contact to the semiconductor material and the gate oxide disposed on at least part of the semiconductor material in the peripheral circuitry;
a first silicide layer disposed on the floating diffusion, a second silicide layer disposed on the transfer gate, and a third silicide layer disposed on the first electrical contact to the semiconductor material;
an isolation layer disposed proximate to the semiconductor material, wherein the transfer gate is disposed between the semiconductor material and the isolation layer; and
a plurality of metal interconnects that extend vertically through the isolation layer, wherein the plurality of metal interconnects includes:
a first metal interconnect electrically coupled to the first silicide layer, wherein a first width of the first silicide layer is equal to a second width of the first metal interconnect; and
a second metal interconnect electrically coupled to the second silicide layer, wherein a third width of the second silicide layer is equal to a fourth width of the second metal interconnect.

2. The image sensor of claim 1, wherein the first silicide layer, the second silicide layer, and the third silicide layer include a same material composition.

3. The image sensor of claim 2, wherein the first silicide layer, the second silicide layer, and the third silicide layer include CoₓSi_{y}.

4. The image sensor of claim 2, wherein the first silicide layer, the second silicide layer, and the third silicide layer include NiₓSi_{y}.

5. The image sensor of claim 2, wherein the first silicide layer, the second silicide layer, and the third silicide layer include an implant element of carbon, nitrogen, or oxygen.

6. (canceled)

7. The image sensor of claim 1, further comprising a third metal interconnect, included in the plurality of metal interconnects, disposed in the isolation layer and electrically coupled to the third silicide layer, and wherein a fifth width of the third silicide layer is equal to a sixth width of the third metal interconnect.

8. The image sensor of claim 7, wherein the plurality of metal interconnects include aluminum, tungsten, or copper.

9. The image sensor of claim 1, wherein the peripheral circuitry includes a transistor, a fourth silicide layer, and a fifth silicide layer, and wherein the fourth silicide layer is disposed on a source terminal of the transistor and the fifth silicide layer is disposed on a gate terminal of the transistor.

10. The image sensor of claim 1, wherein the first silicide layer, the second silicide layer, and the third silicide layer reduce a contact resistance.

11. A method of image sensor fabrication, comprising:
providing a photodiode included in a plurality of photodiodes disposed in semiconductor material and a floating diffusion disposed in the semiconductor material;
providing peripheral circuitry disposed in the semiconductor material including a first electrical contact to the semiconductor material;
forming a transfer gate disposed to transfer image charge from the photodiode to the floating diffusion;
depositing an isolation layer on a surface of the semiconductor material, wherein the transfer gate is disposed between the semiconductor material and the isolation layer;
forming a first silicide layer disposed on the floating diffusion, a second silicide layer disposed on the transfer gate, and a third silicide layer disposed on the first electrical contact to the semiconductor material; and
forming metal interconnects that extend vertically through the isolation layer, wherein the metal interconnects include:
a first metal interconnect electrically coupled to the first silicide layer, wherein a first width of the first silicide layer is equal to a second width of the first metal interconnect; and
a second metal interconnect electrically coupled to the second silicide layer, wherein a third width of the second silicide layer is equal to a fourth width of the second metal interconnect.

12. The method of claim 11, wherein the first silicide layer, the second silicide layer, and the third silicide layer include the same material composition.

13. The method of claim 12, wherein the first silicide layer, the second silicide layer, and the third silicide layer include CoₓSi_{y}.

14. The method of claim 12, wherein the first silicide layer, the second silicide layer, and the third silicide layer include NiₓSi_{y}.

15. (canceled)

16. The method of claim 15, wherein a third metal interconnect, included in the metal interconnects is electrically coupled to the third silicide layer, and wherein a fifth width of the third silicide layer is equal to a sixth width of the third metal interconnect.

17. The method of claim 16, wherein forming the metal interconnects includes:
etching contact holes in the isolation layer;
forming the first silicide layer, the second silicide layer, and the third silicide layer in the contact holes, wherein forming includes depositing a silicon layer and metalizing the silicon layer; and
depositing the metal interconnects in the contact holes.

18. The method of claim 17, further comprising implanting the silicon layer with one of carbon, nitrogen, or oxygen.

19. The method of claim 17, wherein the metal interconnects form Ohmic contacts with the first silicide layer, the second silicide layer, and the third silicide layer.

20. The method of claim 19, wherein the metal interconnects include aluminum, tungsten, or copper.
